(19) United States
(12) Patent Application Publication
(10) Pub. No.: US 2012/0327422 A1
(43) Pub. Date: Dec. 27, 2012

(54) SEMICONDUCTOR OPTICAL INTEGRATED DEVICE AND OPTICAL COHERENCE TOMOGRAPHIC IMAGING APPARATUS PROVIDED WITH THE SEMICONDUCTOR OPTICAL INTEGRATED DEVICE

(75) Inventors: Yasuhisa Inao, Tokyo (JP); Mamoru Uchida, Yokohama-shi (JP); Takeshi Uchida, Tokyo (JP)

(73) Assignee: CANON KABUSHIKI KAISHA, Tokyo (JP)

(21) Appl. No.: 13/523,107

(22) Filed: Jun. 14, 2012

(30) Foreign Application Priority Data
Jun. 21, 2011 (JP) 2011-137422

(51) Int. Cl. H01L 31/12; G01B 9/02; H01L 33/04

(52) U.S. Cl. 356/479; 257/85; 257/13; 257/E33.077; 257/E33.048

(57) ABSTRACT

Provided is a semiconductor optical integrated device, formed by arranging a light emitting element and a light detecting element in a plane of the same substrate, each formed by laminating layers which at least include a first clad layer of a first conductive type, an active layer and a second clad layer of a second conductive type on a substrate, wherein the active layer has a structure where a second active area of a conductive type and an undoped first active area are laminated, and the second active area has the same conductive type as that of the first or second clad layer laminated in the closest position to the second active area. This device suppresses heat generation due to increased operating current and unnecessary light generation at an operation of the light emitting element, and enhancing light absorption efficiency at the an operation of the light emitting element.

### BACKGROUND OF THE INVENTION

1. Field of the Invention

The present invention relates to a semiconductor optical integrated device, and an optical coherence tomographic imaging apparatus provided with the semiconductor optical integrated device.

2. Description of the Related Art

In recent years, an apparatus for performing tomography through use of interference of low coherence light, called Optical Coherence Tomography (OCT), has been put to practical use. In the ophthalmic field, this OCT is used for, for example, acquiring a tomographic image of a fundus segment for diagnosis of retinal detachment, and a tomographic image of an iris in an anterior ocular segment for preliminary diagnosis of glaucoma. Also in fields other than the ophthalmologic field, OCT has been used for observing a tomographic image of a skin, or incorporated into an endoscope or a catheter to attempt tomography of inner wall of a digestive organ or a circulatory organ, and the like.

For such an OCT, a Super Luminescent Diode (SLD) is often used as an optical source to generate low coherence light. This SLD is configured such that spontaneously emitted light generated by current injection is used as seed light, which guides electromagnetic waves in an active layer that has a population inversion due to the current injection, leading to stimulated emission, thereby to amplify light. With a configuration formed such that this amplified light is not reflected at an outlet, a resonator structure is not formed, and a configuration to suppress a laser oscillation is formed. The operation to amplify spontaneously emitted light by light passing through the active layer once, as thus described, is generally called a Super Luminescent mode (SL mode). The SLD as described above has the feature of producing a large output due to the use of the light amplification effect and of acquiring light with strong directivity, as compared with a Light-Emitting Diode (LED).

There has hitherto been well known that in order to stabilize light output from the SLD as above, an operating current is fed back while light from one of the end surfaces of the SLD is monitored by a Photo Diode (PD). In this regard, Japanese Patent Application Laid-Open No. H10-178200 (hereinafter referred to as “Patent Document 1”) proposes a semiconductor optical integrated device where such a PD is formed on a substrate having an identical layer configuration to that of the SLD, to be formed as a one-chip device.

In SLD, the number of quantum wells used for the active layer is typically as less as on the order of one to five so that an operation on an SL mode can be efficiently generated. This is attributable to the fact that, since a current is injected into the active layer to form a population inversion, a required number of carriers is associated with a volume of the active layer, necessitating an increase in current, as in a normal laser. That is, since heat generation of the device becomes significant with increase in required injected current, which leads to deterioration in operating characteristics of the SLD, the volume of the active layer is typically controlled not to become excessively large. In the PD, on the other hand, light absorption efficiency is desirably high so that detected light can be efficiently converted to a current. As thus described, the volume of the active layer that absorbs light is typically made large for enhancing the light absorption efficiency. In the case of the PD having the active layer of the quantum wells, a large number of quantum wells are formed and arrayed, thereby to realize the enhancement. With the absorption efficiency improved in accordance with the number of quantum wells, it is also a general practice to laminate as large a number of quantum wells as ten or more pairs for formation.

### SUMMARY OF THE INVENTION

When the SLD/PD are disposed on the laminated surface of the identical layer configuration formed by laminating semiconductor layers by use of the above typical SLD structure as in Patent Document 1, the volume of the active layer cannot be increased due to constraints of the above-mentioned operating characteristics of the SLD. Hence it is only possible to obtain one to be operated as the PD which has low light absorption efficiency. In order to cope with these, the volume of the active layer may be increased for enhancing light absorption efficiency or an undoped active layer for performing the PD operation may be added to the SLD. However, in such coping processes, since the volume of the active layer, which is to be injected with a current, increases, heat is generated or unnecessary light is generated due to an increase in required current for operation on the SL mode, leading to deterioration in characteristics of the SLD. As thus described, in the SLD/PD integrated device using the identical active layer structure as in Patent Document 1, it has been difficult to simultaneously optimize characteristics of the SLD and the PD.

In view of the above problems, an object of the present invention is to provide a semiconductor optical integrated device which is capable of suppressing, at the time of operation of a light emitting element, heat generation and unnecessary light generation due to an increase in operating current, and enhancing light absorption efficiency at the time of operation of a light detecting element, in constituting the semiconductor optical integrated device disposed with the light emitting element and the light detecting element in a laminated surface of an identical layer configuration formed by laminating a plurality of semiconductor layers, and to provide an optical coherence tomographic imaging apparatus provided with the semiconductor optical integrated device.

The semiconductor optical integrated device of the present invention is formed by arranging a light emitting element and a light detecting element in a plane of the same substrate, each formed by laminating layers which at least include a first clad layer of a first conductive type, an active layer and a second clad layer of a second conductive type on a substrate, in which the active layer has a structure where a second active area of a conductive type and an undoped first active area are laminated, and the second active area has the same conductive type as that of the first or second clad layer laminated in the closest position to the second active area.

Further, an optical coherence tomographic imaging apparatus of the present invention is characterized by including the semiconductor optical integrated device as an optical source.

According to the present invention, it is possible to realize a semiconductor optical integrated device which is capable of suppressing heat generation and unnecessary light generation due to an increase in operating current at the time of operation of a light emitting element, and enhancing light absorption efficiency at the time of operation of a light detecting element, in constituting the semiconductor optical integrated device disposed with the light emitting element and the light detecting element in a laminated surface of an identical layer configuration formed by laminating a plurality of semiconductor layers, and to realize an optical coherence tomographic imaging apparatus provided with the semiconductor optical integrated device.

Further features of the present invention will become apparent from the following description of exemplary embodiments with reference to the attached drawings.

### BRIEF DESCRIPTION OF THE DRAWINGS

FIG. 1 is a view for explaining a layer configuration of a semiconductor optical integrated device in an embodiment of the present invention.

FIG. 2 is an schematic view of a band diagram of a layer configuration of the semiconductor optical integrated device in the embodiment of the present invention.

FIGS. 3A, 3B and 3C are schematic views of the semiconductor optical integrated device in the embodiment of the present invention.

FIG. 4 is a view for explaining a layer configuration of a semiconductor optical integrated device in Example 1 of the present invention.

FIGS. 5A and 5B are schematic views of the semiconductor optical integrated device in Example 1 of the present invention.

FIG. 6 is a view for explaining a layer configuration of a semiconductor optical integrated device in Example 2 of the present invention.

FIG. 7 is a schematic view of a semiconductor optical integrated device in Example 2 of the present invention.

FIG. 8 is a schematic view of an optical coherence tomographic imaging apparatus provided with the semiconductor optical integrated device in Example 4 of the present invention.

FIG. 9 is a view showing a configuration where a plurality of semiconductor optical integrated devices are combined by an optical waveguide in the embodiment of the present invention.

### DESCRIPTION OF THE EMBODIMENTS

Preferred embodiments of the present invention will now be described in detail in accordance with the accompanying drawings.

In the present invention, a light detecting element and a light emitting element which are formed by laminating layers at least including a first clad layer of a first conductive type, an active layer and a second clad layer of a second conductive type, are arranged in a plane of the same substrate, and an SLD (light emitting element) operation can be performed at the time of forward bias, whereby an PD (light detecting element) operation having favorable absorption efficiency can be performed at the time of reverse bias.

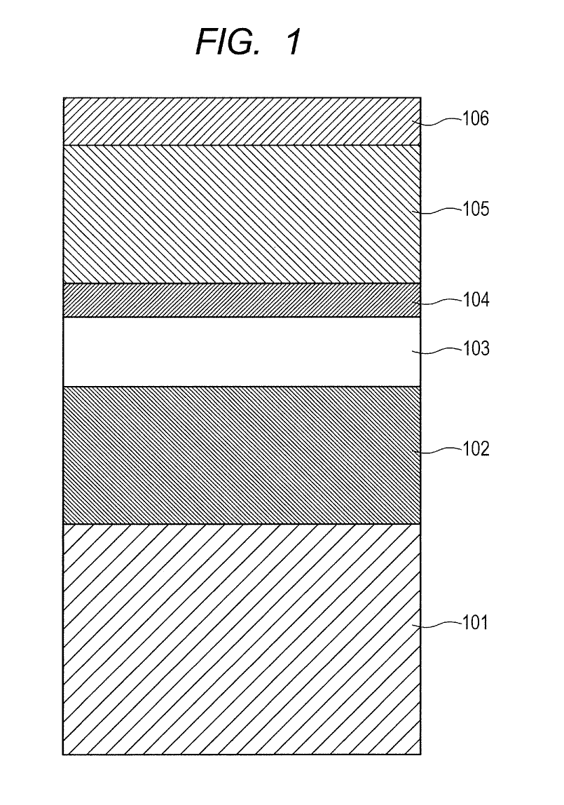

Referring to FIG. 1 as a specific embodiment of the layer configuration, a view for explaining a layer configuration of a semiconductor optical integrated device in the present embodiment is represented. As shown in FIG. 1, in the semiconductor optical integrated device of the present embodiment, each layer is laminated in the following order. First, a first clad layer 102 of a first conductive type and an undoped first active area 103 are laminated on a substrate 101 of the first conductive type. Thereon, a second active area 104 of a second conductive type configured to absorb light, a second clad layer 105 of the second conductive type, and a contact layer 106 of the second conductive type are then laminated. As thus described, the second active area 104 has the same second conductive type as that of the second clad layer 105.

The first clad layer 102 and the second clad layer 105 are layers having lower refractive indexes than the first active area 103 and the second active area 104, and serving to confine light to the first and second active areas. When the undoped first active area 103 is configured of quantum wells for example, it is configured of quantum wells and barriers surrounding the wells. That is, the first active area 103 is defined herein as an area including the entire undoped area.

The second active area 104 of the second conductive type is placed between the first active area 103 and the second clad layer 105, and refers to the entire area doped to be of the second conductive type. For example, even when the second active area 104 is a quantum well placed between the barrier layers, the entire area doped to be of the second conductive type is taken as the second active area 104.

Other than the configuration described here, the second active area 104 may be provided between the first active area 103 and the first clad layer 102. In this case, the second active area 104 becomes the first conductive type, and refers to the whole doped area placed between the first clad layer 102 and the first active area 103. That is, the second active area is placed between the first active area and the first or second clad layer, and has the same conductive type as that of the contacting clad layer.

As thus described, the active layer is provided with the structure where the second active area of the conductive type and the undoped first active area are laminated, and this second active area has the same conductive type as that of the first or second clad layer laminated in a position closest to the second active area. Herein, an active layer is referred to as both of the first active area and the second active area.

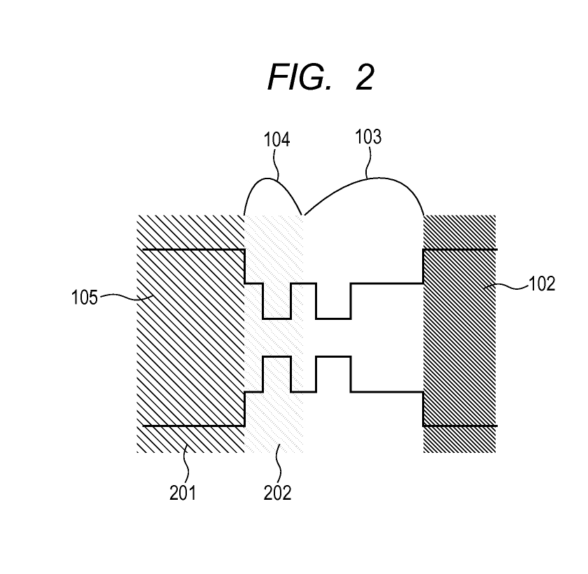

Referring to FIG. 2 as an image view of a band lineup and a doping distribution in the above laminated structure, which represents an example of using quantum wells both in the first active area 103 and the second active area 104. The respective areas are referred to as the first active area 103 and the second active area 104 while including barrier layers surrounding the quantum wells.

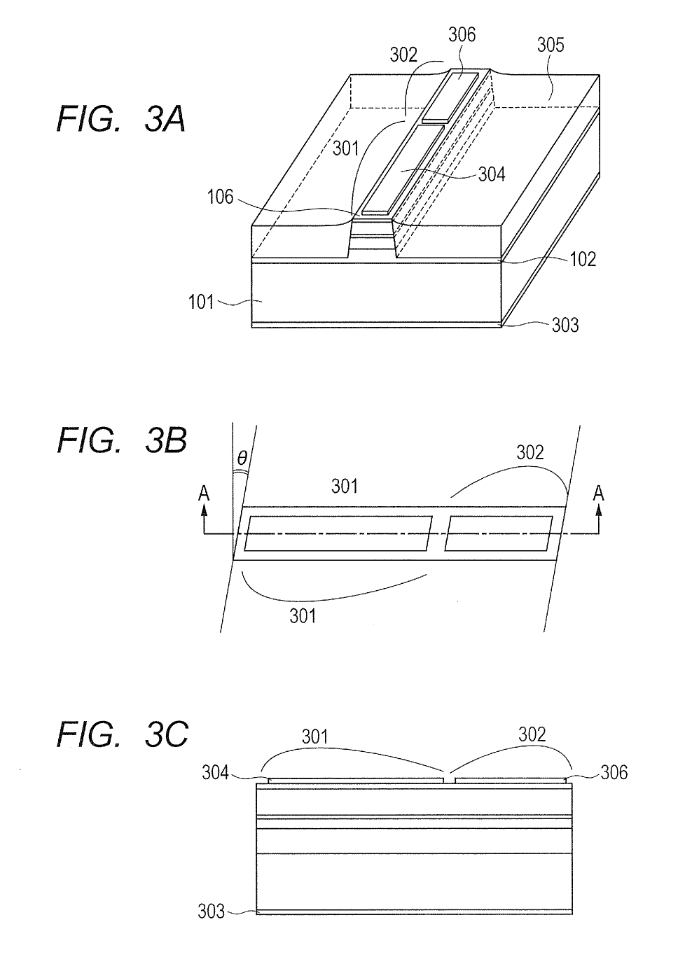

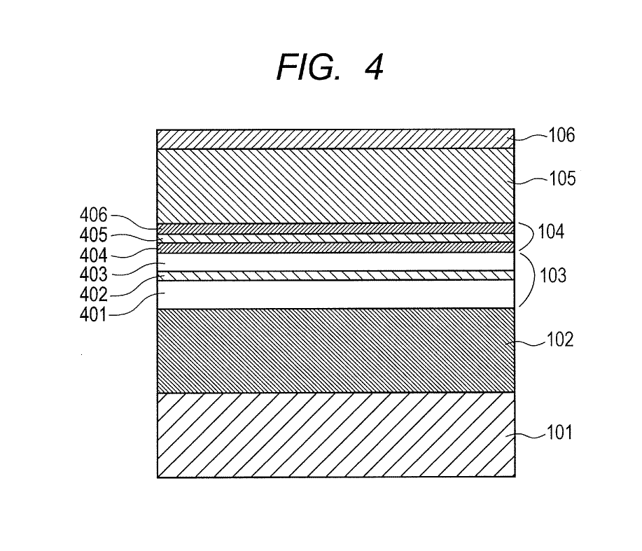

FIG. 3A is a perspective view of a device obtained by producing such a structure that the SLD/PD are arranged on the same substrate and operated in the layer configuration shown in FIGS. 1 and 2, FIG. 3B is a plan view of this device, and FIG. 3C is a sectional view of 3C-3C of this device. A PD section 302 is arranged at a position where it can detect light emitted from an SLD section 301.

Since the both sections are arranged in such a relative positional relation, a signal in accordance with light emitted from the SLD section 301 and detected in the PD section 302 can be obtained, and by feeding back to control a drive current of the SLD such that this signal becomes constant, an SLD having with a stable light output can be realized.

In FIGS. 3A, 3B and 3C, the SLD and the PD are not separated from each other, and the respective layers are formed in a connected form. In the SLD section 301, when a forward bias voltage is applied to between an SLD/PD common electrode 303 formed in contact with the substrate 101 and an SLD electrode 304 formed in contact with the contact layer 106 for current injection, this device is operated as SLD.

At the time of the forward bias, majority carriers are injected into the second active area 104. However, since the area has been doped, the opposite carriers cannot enter into this area. For this reason, recombination hardly occurs in the second active area and the carries are not consumed. In the second active area 104, after injection of carriers to a certain level, the carries pass through the second active area 104 to reach the undoped first active area 103. The carries injected from the first clad layer 102 of the first conductive type provided on the side where the second active area does not exist and the carries having passed through the second active area 104 are recombined in the first active area 103, to emit light.

For example, as shown in FIG. 3A, a ridge-shaped waveguide is formed to constitute the SLD section 301. Specifically, etching is performed from the top side of the layer configuration to the first clad layer 102 into a stripe shape to form a ridge structure, and the ridge structure is then embedded (embedded section 305) using a material with a closer refractive index to those of the first and second clad layers, to form a ridge-shaped waveguide. At this time, it is possible to appropriately determine a width and a length of the stripe of the ridge in accordance with design. The SLD formed with the ridge-shaped waveguide has a refractive-index waveguide structure, and an active layer section with a higher refractive index (area including both the first and second active areas in the present invention) is surrounded by a clad layer with a lower refractive index (including the material embedded with the first and second clad layers and the ridge structure). Thus a waveguide structure with a difference in refractive index is formed. Travelling of light inside the waveguide applied with the forward bias voltage leads to occurrence of stimulated emission, thereby the SLD section performs an SL-mode operation.

Other than the SLD structure formed by means of the refractive-index waveguide, the SL-mode operation can also be performed by a gain waveguide having no ridge structure. This structure called a gain waveguide is one limiting a carrier-injected area to a striped shape without forming the ridge structure, thereby to amplify only light therealong and performs the SL-mode operation.

It is to be noted that the present invention is one having a feature in its layer configuration for forming the SLD and PD, and it is not one being limited to either the ridge type or the gain waveguide type.

In the SLD section 301, a device end surface is formed having an inclined angle 0 of 5 to 9 degrees from an orthogonal line to the stripe as shown in FIG. 3B. This alleviates reflection on the end surface to prevent formation of a Fabry-Perot resonator and thus suppress laser oscillation. Otherwise, an antireflection film may be formed on this end surface to further alleviate reflection on the end surface.

The PD section 302 is formed in a similar structure to a substantially SLD. For example, the ridge-shaped waveguide may be provided in a combined form with the SLD as in FIG. 3A. Otherwise, the electrode may be formed in a stripe shape without forming a waveguide, to limit an area to operate as the PD. Otherwise, the electrode may be formed all over the device section so as to allow uniform application of a voltage to the PD section without limiting the shape of the electrode.

The PD section 302 performs an operation by application of a reverse bias voltage to an SLD/PD common electrode 303 formed in contact with the substrate 101, and to a PD electrode 306 formed in contact with the contact layer 106. A doping concentration and a distance from the second clad layer 105 are controlled such that application of this reverse bias voltage leads to depletion of the second active area 104 of the second conductive type.

It is a feature to be realized by the layer configuration of the present invention that application of this reverse bias voltage leads to depletion of the second active area 104.

In order for the second active area 104 to be depleted at the time of reverse bias voltage application, a doping concentration of the doped area 202 in the second active area 104 is desirably lower than a doping concentration of the doped area 201 in the second clad layer 105 shown in FIG. 2. For example, when a doping concentration of the second clad layer 105 is 1E+18 (cm⁻³), a doping concentration of the second active area 104 is desirably on the order of 1E+17 (cm⁻³). In the case of having such a doping concentration difference, when a reverse bias voltage of the order of about −2 to −5 V is applied to between the second clad layer 105 and the second active area 104, a depletion area of the order of about 15 to 25 nm is formed on the second active area 104 side from the interface of the second clad layer 105 and the second active area 104.

The doping concentration cited here is just an example, and no limitation is intended as far as depleting of the second active area 104 at the time of reverse bias application, which is an essence of the present invention, is realized.

When light is incident on the PD section 302 at the time of reverse bias voltage application, the first active area 103 absorbs light and generates carriers, which can be taken out as a current. At this time, with the second active area 104 being depleted, the second active area 104 also absorbs light and generates carriers, which can also be taken out as a current. For this reason, the number of layers which absorb light and from which a signal can be taken out as a current is larger than in the case of using a normal SLD as the PD. That is, it can be operated as a PD that absorbs a large amount of light.

In the case of the second active area 104 being not depleted and remaining to be of the second conductive type at the time of reverse bias application, even when light is absorbed and carriers are generated, minority carriers in the second conductive type cannot move, and thus cannot be taken out as a current. For this reason, depletion of the second active area 104 at the time of reverse bias application is an important matter for the present invention.

When the end surface exists by formation of a groove between the SLD and the PD or by some other means, the end surface of the PD section 302 may have an inclination of 5 to 9 degrees as does that of the SLD section 301. The end surface may further be formed with an antireflection film. This allows incident light to efficiently enter inside the PD without reflection, and a signal can be taken out as a larger amount of current.

Although the case was described in FIG. 2 where the first active area 103 and the second active area 104 of the present invention have the same band gap, the band gap of the first active area 103 may be larger than the band gap of the second active area 104. With such a band-gap relation formed, the absorption edge of the second active area 104 is located on a longer wavelength side than a wavelength of light emitted from the first active area 103 at the time of operation of the SLD. Hence it is possible to absorb a large portion of light emission wavelength in the second active area 104, so as to perform an operation as a more efficient PD.

Otherwise, the band gap of the first active area 103 may be smaller than the band gap of the second active area 104. In this case, the absorption edge of the second active area 104 is located on a shorter wavelength side than the peak of light emission from the first active area 103. Hence it is possible to reduce an absorbed amount of light in the second active area 104 at the time of operation of the SLD, making an efficient SLD operation possible.

Although in the above explanation the structure is referred in which two active areas which are the first and second active areas are exist, it should be noted that the present invention is not limited to this. Specifically, a configuration with the existence of a third active area is adopted, where the third active area has the same conductive type as that of the first or second clad layer laminated in the closest position to the third active area. At that time, a doping concentration of the third active area is desirably made lower than the doping concentration of the first or second clad layer laminated in the closest position to the third active area. For example, there can be adopted a configuration where the third active area of the same conductive type as that of the first clad layer 102 is arranged between the first clad layer 102 of the first conductive type and the first active area 103.

This third active area serves in the same manner as the second active area, except that a polarity of its conductive type is opposite to that of the second active area. Then, in the case of arranging such a third active area, there can be adopted a configuration where band gaps of the second active area and/or the third active area are smaller than the band gap of the first active area. Alternatively, there can be adopted a configuration where the band gaps of the second active area and/or the third active area are larger than the band gap of the first active area. Also as for a doping concentration of the third active area, it is desirably made lower than the doping concentration of the first clad layer.

With the third active area arranged as thus described, the third active area is also depleted at the time of reverse bias operation of the PD, to increase the number of layers which absorb light and from which generated carries are taken out as a current, leading to an operation as a more efficient PD.

Further, there can also be formed a configuration provided with a plurality of combinations of the SLD/PD described in FIG. 3A, and the plurality of semiconductor optical integrated devices are arranged in an array form on the substrate, and used as an array optical source. At that time, part of the plurality of semiconductor optical integrated devices may be combined by an optical waveguide, and for example, light of the SLD may be combined by a waveguide, to form one outlet. This facilitates combination of light toward the outside of the device, thereby to form an easy-to-use configuration. Further, there may be formed a configuration where each of the plurality of semiconductor optical integrated devices is combined by the optical waveguide, and for example, the plurality of SLDs and the PD are combined to the optical waveguide as in FIG. 9. When the structure is taken where the plurality of SLDs and PDs are combined by the waveguide, intensities of light emitted from the plurality of SLDs with different injected currents can be measured using one PD.

According to the configuration of the semiconductor optical integrated device of the present embodiment where the light emitting element and the light detecting element are disposed in the laminated surface of the identical layer configuration, it is possible to improve light use efficiency at the time of operation of the PD. Further, this enables provision of the SLD that stably outputs light. Moreover, applying this optical source to an optical coherence tomographic imaging apparatus enables acquisition of a stable tomographic image.

### EXAMPLE 1

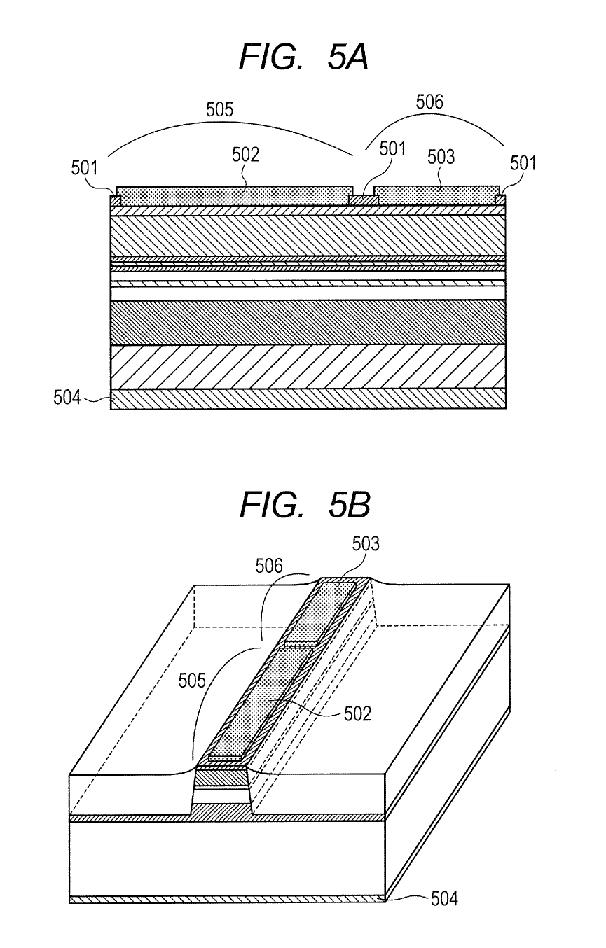

An example of a semiconductor optical integrated device applied with the present invention will be described as Example 1 with referring to FIGS. 4, 5A and 5B.

The semiconductor optical integrated device in the present example is provided with a layer configuration as shown in FIG. 4.

A first clad layer of an n-type Al_{0.5}GaAs (thickness of 1.2 μm, doping concentration of 1E+18 (cm⁻³)) corresponding to the first clad layer 102 of FIG. 1 is formed on an n-type GaAs substrate corresponding to the substrate 101 of FIG. 1. A barrier layer 401 of undoped Al_{0.2}GaAs (thickness of 0.096 μm), a light-emitting quantum well 402 of undoped GaAs (thickness of 0.008 μm), and a barrier layer 403 of undoped Al_{0.2}GaAs (thickness of 0.076 μm) are formed as the first active area 103 on the first clad layer.

A barrier layer 404 of p-type Al_{0.2}GaAs (thickness of 0.004 μm, doping concentration of 1E+17 (cm⁻³)), a light-absorbing quantum well 405 of p-type GaAs (thickness of 0.008 μm, doping concentration of 1E+17 (cm⁻³)), and a barrier layer 406 of p-type Al_{0.2}GaAs (thickness of 0.008 μm, doping concentration of 1E+17 (cm⁻³)) are formed as the second active area 104 on the first active area 103.

Thereon, a second clad layer of a p-type Al_{0.5}GaAs (thickness of 1.2 μm, doping concentration of 1E+18 (cm⁻³)) corresponding to the second clad layer 105 of FIG. 1 and a contact layer of a p-type GaAs (thickness of 0.05 μm, doping concentration of 1E+19 (cm⁻³)) corresponding to the contact layer 106 of FIG. 1 are formed in this order.

FIG. 5A is a sectional view showing a layer configuration of the device of the present example, and FIG. 5B is a perspective view of the device of the present example.

On the substrate formed with the layer configuration as described above, a ridge-shaped waveguide is formed by photolithography and dry etching. This ridge-shaped waveguide is formed with a stripe width of 3 to 10 μm, for example. Since a light-emitting end surface of the SLD is formed by cleavage, the waveguide is formed in a direction having an inclined angle of about 5 to 10 degrees with respect to the cleavage surface in order to suppress reflection of light on the light-emitting end surface.

After formation of the ridge, undoped Al_{0.2}GaAs is subjected to crystal growth and the ridge side surface is embedded, to form an embedded section. Subsequently, SiO₂ is formed as an insulating film 501, SiO₂ in an electrode formation section is removed to expose a contact layer, and films of metal with a two-layered structure of Ti and Au are then formed in the SLD section and the PD section in a separated manner as an SLD electrode 502 and a PD electrode 503.

Next, a film of metal as laminated layers of AuGe/Ni/Au is formed as an SLD/PD common electrode 504 on the back surface of the substrate. Subsequently, the substrate is cleaved so as to have a stripe length of the order of 0.5 to 5 mm. Further, an antireflection film is formed by CVD in order to further reduce a reflectance of the light-emitting surface of the SLD.

By the above process, an SLD section 505 and a PD section 506 can be formed in the shape of being combined to the same substrate.

A forward bias is applied to the SLD section 505 and a reverse bias is applied to a PD section 506 so that those respectively operate as the SLD/PD. At this time, by application of a reverse bias of the order of about −15 to −30 V to the PD section 506, the second active area is depleted to allow generation of a photo current. This allows both the first active area and the second active area to absorb light and generate a photo current, leading to an operation as a more efficient PD.

Simultaneous driving of the SLD/PD allows monitoring of an intensity of light, emitted from the SLD, by means of the PD. Feeding back the SLD-driven current for adjustment so as to stabilize a signal of the PD enables the use as an SLD with a stable light emission intensity.

### EXAMPLE 2

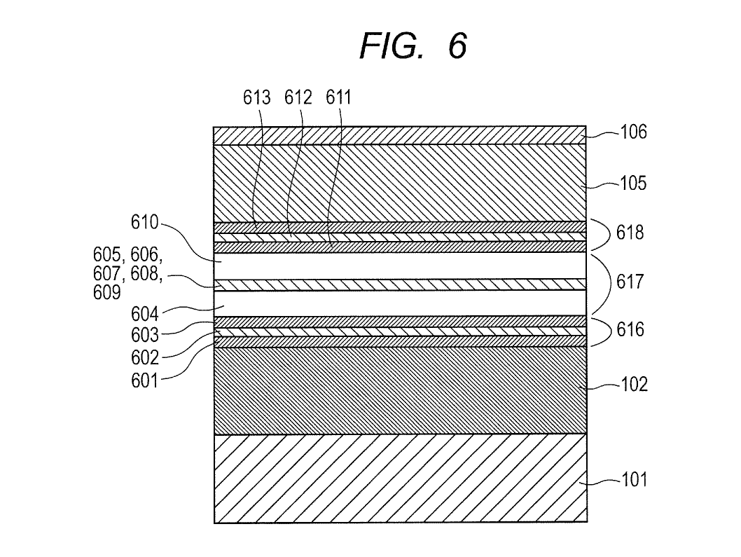

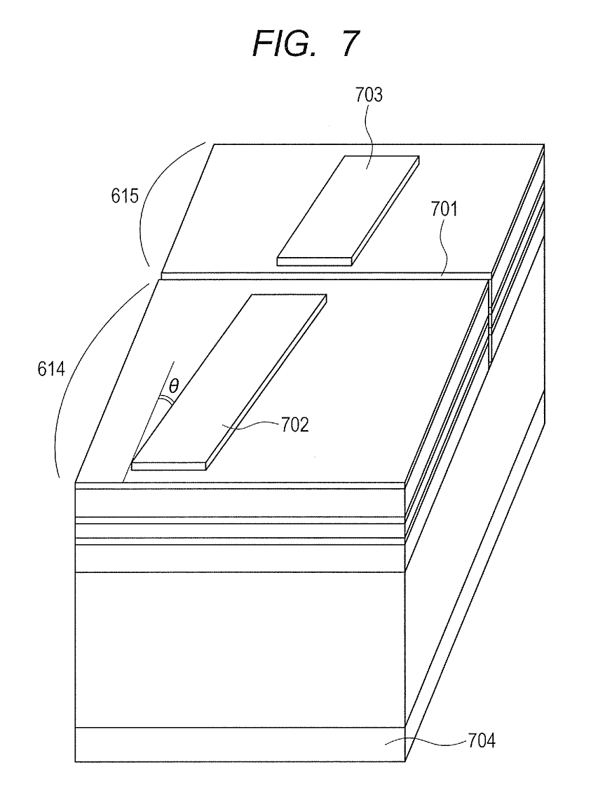

An example of the semiconductor optical integrated device applied with the present invention will be described as Example 2 with referring to FIGS. 6 and 7.

The semiconductor optical integrated device in the present example is provided with a layer configuration as shown in FIG. 6.

A first clad layer of an n-type Al_{0.5}GaAs (thickness of 1.2 μm, doping concentration of 1E+18 (cm⁻³)) corresponding to the first clad layer 102 of FIG. 1 is formed on an n-type GaAs substrate corresponding to the substrate 101 of FIG. 1. Next, a barrier layer 601 of n-type Al_{0.2}GaAs (thickness of 0.005 μm, doping concentration of 1E+17 (cm⁻³)), a second light-absorbing quantum well 602 of n-type GaAs (thickness of 0.008 μm, doping concentration of 1E+17 (cm⁻³)), and a barrier layer 603 of n-type Al_{0.2}GaAs (thickness of 0.005 μm, doping concentration of 1E+17 (cm⁻³)) are formed as a third active area 616 on the first clad layer.

A barrier layer 604 of undoped Al_{0.2}GaAs (thickness of 0.07 μm), a light-emitting quantum well 605 of undoped Al_{0.015}GaAs (thickness of 0.004 μm), a barrier layer 606 of undoped Al_{0.2}GaAs (thickness of 0.05 μm), a light-emitting quantum well 607 of undoped Al_{0.015}GaAs (thickness of 0.006 μm), a barrier layer 608 of undoped Al_{0.2}GaAs (thickness of 0.05 μm), a light-emitting quantum well 609 of undoped Al_{0.015}GaAs (thickness of 0.008 μm), and a barrier layer 610 of undoped Al_{0.2}GaAs (thickness of 0.07 μm) are formed as a first active area 617 on the third active area 616.

A barrier layer 611 of p-type Al_{0.2}GaAs (thickness of 0.005 μm, doping concentration of 1E+17 (cm⁻³)), a light-absorbing quantum well 612 of p-type GaAs (thickness of 0.008 μm, doping concentration of 1E+17 (cm⁻³)), and a barrier layer 613 of p-type Al_{0.2}GaAs (thickness of 0.005 μm, doping concentration of 1E+17 (cm⁻³)) are formed as a second active area 618 on the first active area 617.

Thereon, a second clad layer of a p-type Al_{0.5}GaAs (thickness of 1.2 μm, doping concentration of 1E+18 (cm⁻³)) corresponding to the second clad layer 105 of FIG. 1 and a contact layer of a p-type GaAs (thickness of 0.05 μm, doping concentration of 1E+19 (cm⁻³)) corresponding to the contact layer 106 of FIG. 1 are then formed in this order.

FIG. 7 shows a perspective view of devices of the SLD/PD of a gain waveguide formed in the above layer configuration.

In this substrate, a groove 701 configured to separate an SLD section 614 and a PD section 615 is formed by photolithography and dry etching. Subsequently, SiO₂ as an insulating film is formed, and the SiO₂ is then removed from part of the surface of each of the SLD section 614 and the PD section 615 by photolithography and wet etching so as to form a stripe shape. Thereafter, Ti and Au as p-type electrode materials are evaporated on this portion so as to separate the SLD section 614 and the PD section 615 from each other, thereby forming an SLD electrode 702 and a PD electrode 703. The GaAs substrate is then polished into a thickness of 100 μm, and AuGe, Ni and Au are evaporated on the back surface of the substrate, to form an SLD/PD common electrode 704. Subsequently, the substrate is cleaved such that the SLD/PD have stripe lengths of the order of 0.5 to mm. As in Example 1, the cleavage surface and a waveguide direction of the stripe have an inclined angle θ of 5 to 9 degrees. Further, an antireflection film is formed on this cleavage surface as in Example 1.

By such a manufacturing method, the SLD/PD of the gain waveguide type are formed. Forming the groove between the SLD section and the PD section enables clear separation of current channels in the SLD section and the PD section, so as to prevent unnecessary current diffusion.

Unlike Example 1 where the doped active area was only the second active area, in the present example the doped third active area is also provided. These two doped active areas are depleted at the time of reverse bias application as in Example 1. That is, as compared with the normal SLD structure, two active areas to absorb light and change it to a current at the time of reverse bias are added. It is thereby possible to perform an operation as a PD with a higher absorption efficiency than in Example 1.

Further, in the present example, the quantum wells of Al_{0.015}GaAs (thicknesses of 0.008, 0.006, 0.004 μm) are used as the first active area, and the respective wells have emission wavelength peaks of 830 nm, 815 nm and 790 nm. As opposed to this, the quantum well of GaAs (thickness of 0.008 μm) is used as the second and third active areas, and the second and third active areas have small band gaps as compared with the first active area. The absorption edge of this quantum well is about 840 nm. For this reason, a large portion of a light emission wavelength of light emitted from the first active quantum well at the time of the operation of the SLD is in an absorption spectrum of the second and third active quantum well. Hence light with many wavelengths are absorbed in the PD section as compared with Example 1, and it can thus serve as a highly efficient PD section.

### EXAMPLE 3

As Example 3, a constitutional example will be described which is obtained by changing the doped section of the second active area in Example 1.

The second active area used in the present example has a layer configuration formed of a barrier layer of p-type Al_{0.2}GaAs (thickness of 0.004 μm, doping concentration of 1E+17 (cm⁻³)), a quantum well of undoped GaAs (thickness of 0.008 μm), and a barrier layer of p-type Al_{0.2}GaAs (thickness of 0.008 μm, doping concentration of 1E+17 (cm⁻³)).

Not doping only the quantum well section out of the doped second active area can lead to improvement in crystalline quality of the second active area. Improvement in crystalline quality suppresses non-emission recombination of carriers generated by absorption of light, and thus a current can be taken out in a more efficient manner.

### EXAMPLE 4

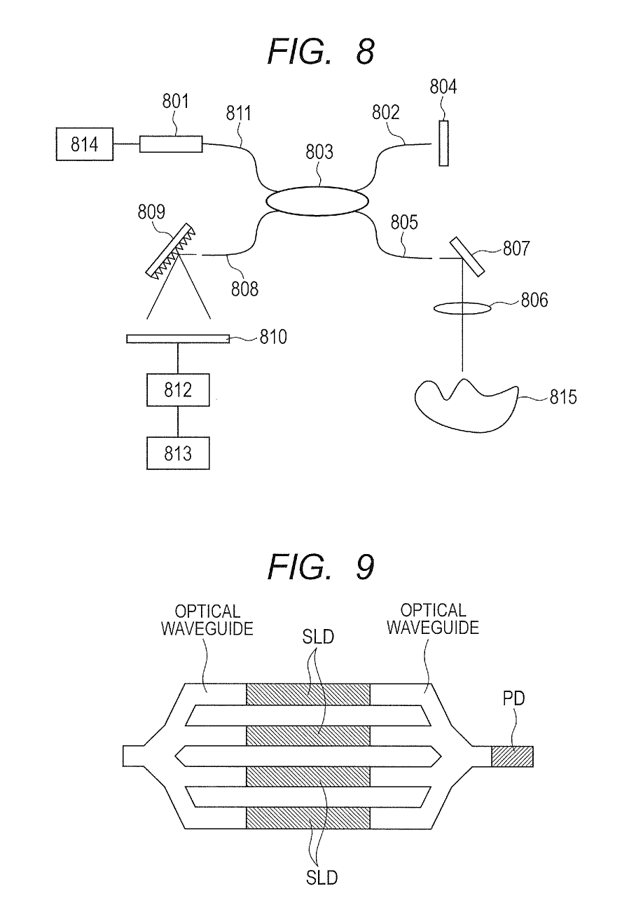

A constitutional example of an optical coherence tomographic imaging apparatus (OCT system) provided with the semiconductor optical integrated device of the present invention will be described as Example 4 with referring to FIG. 8.

As shown in FIG. 8, the optical coherence tomographic imaging apparatus of the present example is provided with an SLD/PD 801 of the present invention as an optical source section, a reference beam optical path fiber 802 constituting a reference section, a fiber coupler 803 constituting an interference section, and a reflection mirror 804. An inspection beam optical path fiber 805 constituting a specimen measuring section, an irradiated beam collection optical system 806, and an irradiated position scanning mirror 807 are connected. On top of this, a beam detection fiber 808 constituting a beam detecting section, a spectrometer 809 and a line sensor 810 are arranged. The optical coherence tomographic imaging apparatus can be configured such that an irradiation fiber 811, a signal processor 812 constituting an image processing section, and an image output monitor 813 are connected, and an optical source controller 814 constituting the optical source section are then connected. Numeral 815 denotes a test object (specimen).

The SLD/PD 801 as the optical source are controlled by the optical source controller 814 in terms of an injected current to the SLD such that a light output becomes stable in association with a detecting signal in the PD. Light irradiated from the SLD/PD is divided by the fiber coupler and introduced into the reference beam optical path fiber and the inspection beam optical path fiber. The reflection mirror is arranged at the tip of the reference beam optical path fiber, and a beam reflected by the reflection mirror is introduced into the beam detection fiber and divided into spectrums by the spectrometer, which reach the line sensor. Simultaneously with this, the test object is irradiated with the beam introduced by the fiber coupler into the inspection beam optical path fiber, and backscattering beams (in the present specification, beams including a backscattering beam are expressed as a reflected beams) are generated from the inside and the surface of the test object. These beams are introduced from the fiber coupler into the beam detection fiber through irradiated beam collection optical system, and beams divided into spectrums by the spectrometer reach the line sensor. The beam reflected from the reflection mirror and the beam from the test object interfere with each other and reach the line sensor, and an interference signal is acquired as comprised on light intensity of each wavelength.

This acquired signal is subjected to Fourier transform by the signal processor to transform the acquired spectrum signal to information of a depth direction of the test object, which can be acquired as a tomographic image of the test object. This acquired depth information can be displayed on an image output monitor. Simultaneously, a drive signal of the irradiated position scanning mirror is oscillated from the signal processor, and an interference signal is acquired in synchronization with this, and thus a one-dimensional and two-dimensional tomographic images can be acquired.

By use of the SLD/PD of the present example for the optical coherence tomographic imaging apparatus, it is possible to acquire a signal with a stable light intensity and stabilize a signal intensity of a tomographic image, so as to acquire a favorable tomographic image. Further, the optical coherence tomographic imaging apparatus of the present example can also be used, for example as a fundus OCT (Optical Coherence Tomography) used for ophthalmic care. Moreover, it is also usable as an OCT for medical purposes and an OCT for industrial uses, and use applications thereof are not particularly limited.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-137422, filed Jun. 21, 2011, which is hereby incorporated by reference herein in its entirety.

What is claimed is:

1. A semiconductor optical integrated device, formed by arranging a light emitting element and a light detecting element in a plane of the same substrate, each formed by laminating layers, at least including a first clad layer of a first conductive type, an active layer and a second clad layer of a second conductive type, on a substrate,
wherein the active layer has a structure where a second active area of a conductive type and an undoped first active area are laminated, and
the second active area has the same conductive type as that of the first or second clad layer laminated in the closest position to the second active area.

2. The semiconductor optical integrated device according to claim 1, wherein a doping concentration of the second active area is lower than a doping concentration of the first or second clad layer laminated in the closest position to the second active area.

3. The semiconductor optical integrated device according to claim 1, wherein the device has a third active area of a conductive type placed between the first or second clad layer and the second and first active areas, and
the conductive type of the third active area is the same as the conductive type of the first or second clad layer laminated in the closest position to the third active area.

4. The semiconductor optical integrated device according to claim 1, wherein a doping concentration of the third active area is lower than a doping concentration of the first or second clad layer laminated in the closest position to the third active area.

5. The semiconductor optical integrated device according to claim 1, wherein a band gap of the second active area is smaller than a band gap of the first active area.

6. The semiconductor optical integrated device according to claim 3, wherein a band gap of the third active area is smaller than a band gap of the first active area.

7. The semiconductor optical integrated device according to claim 3, wherein band gaps of the second active area and the third active area are smaller than a band gap of the first active area.

8. The semiconductor optical integrated device according to claim 1, wherein a band gap of the second active area is larger than a band gap of the first active area.

9. The semiconductor optical integrated device according to claim 3, wherein a band gap of the third active area is larger than a band gap of the first active area.

10. The semiconductor optical integrated device according to claim 3, wherein band gaps of the second active area and the third active area are larger than a band gap of the first active area.

11. The semiconductor optical integrated device according to claim 1, wherein the second active area has a quantum well.

12. The semiconductor optical integrated device according to claim 3, wherein the third active area has a quantum well.

13. The semiconductor optical integrated device according to claim 3, wherein the second active area and the third active area have quantum wells.

14. A semiconductor optical integrated device, wherein a plurality of semiconductor optical integrated devices according to claim 1 are provided, and the plurality of semiconductor optical integrated devices are arranged in an array form on the substrate.

15. The semiconductor optical integrated device according to claim 14, wherein each of the plurality of semiconductor optical integrated devices arranged in the array form on the substrate is connected by an optical waveguide, or part thereof is combined by an optical waveguide.

16. The semiconductor optical integrated device according to claim 1, wherein light generated from the light emitting element can be detected in the light detecting element by application of a forward bias voltage to the light emitting element and application of a reverse bias voltage to the light detecting element.

17. An optical coherence tomographic imaging apparatus, including:
an optical source section provided with the semiconductor optical integrated device according to claim 1 as an optical source;
a specimen measuring section configured to apply a beam emitted from the optical source section to a specimen and transmits a reflected beam from the specimen;
a reference section configured to apply a beam emitted from the optical source section to a reflection mirror and transmits a reflected beam from the reflection mirror;
an interference section configured to make the reflected beam from the specimen measuring section and the reflected beam from the reference section interfere with each other;
a beam detecting section configured to detect an interference beam from the interference section; and
an image processing section configured to obtain a tomographic image of the specimen based on the beam detected in the beam detecting section.
